(19) United States
(12) Patent Application Publication
(10) Pub. No.: US 2013/0099835 A1
(43) Pub. Date: Apr. 25, 2013

(54) CALIBRATION APPARATUS FOR PERFORMING PHASE DETECTION/EDGE DISTANCE DETECTION UPON SIGNALS AND RELATED CALIBRATION METHOD THEREOF

(71) Applicants: You-Wen Chang, Hsinchu City (TW); Yi-Sung Chan, Hsinchu City (TW); Jin-Bin Yang, Hsinchu City (TW); Chang-Po Ma, Hsinchu City (TW)

(72) Inventors: You-Wen Chang, Hsinchu City (TW); Yi-Sung Chan, Hsinchu City (TW); Jin-Bin Yang, Hsinchu City (TW); Chang-Po Ma, Hsinchu City (TW)

(21) Appl. No.: 13/280,341

(22) Filed: Oct. 25, 2011

(51) Int. Cl. H03L 7/00

(52) U.S. Cl. 327/141

(57) ABSTRACT

An exemplary calibration apparatus includes a detecting circuit and a calibrating circuit. The detecting circuit is arranged for generating a detection result by detecting relationship between edges of a plurality of signals generated from a plurality of signal sources, wherein at least one of the edges is a falling edge. The calibrating circuit is coupled to the detecting circuit, and arranged for calibrating at least one of the signal sources according to the detection result. An exemplary calibration method includes the following steps: generating a detection result by detecting relationship between edges of a plurality of signals generated from a plurality of signal sources, wherein at least one of the edges is a falling edge; and calibrating at least one of the signal sources according to the detection result.

### BACKGROUND

The disclosed embodiments of the present invention relate to calibrating signals transmitted from a transmitter end to a receiver end, and more particularly, to a calibration apparatus for performing phase detection/edge distance detection upon signals transmitted from a transmitter end to a receiver end and related calibration method thereof.

Regarding certain applications, a transmitter chip communicates with a receiver chip via a plurality of transmission lines. Therefore, the transmitter chip transmits a plurality of signals at the same time for delivering control information or data information to the receiver chip. Taking an optical storage apparatus for example, a controller chip may generate a plurality of write enable (WEN) signals to control laser power of a laser diode disposed on an optical pick-up unit (OPU) through a plurality of channels between the controller chip and the OPU, where a gray code for laser power control has a plurality of bits delivered by the transmitted WEN signals simultaneously and respectively. However, if there are non-ideal effects present at the controller chip, the OPU, and/or the interface between the controller chip and the OPU, one or more of the WEN signals may be distorted. For example, the misalignment between the WEN signals may make the transmitted gray code erroneously decoded at the OPU, leading to incorrect power control of the laser diode.

Thus, there is a need for an innovative signal calibration design which can calibrate the signal sources to compensate the transmitted signals for the distortion caused by undesired non-ideal effects.

### SUMMARY

In accordance with exemplary embodiments of the present invention, a calibration apparatus for performing phase detection/edge distance detection upon signals transmitted from a transmitter end to a receiver end and related calibration method thereof are proposed to solve the above-mentioned problems.

According to a first aspect of the present invention, an exemplary calibration apparatus is disclosed. The exemplary calibration apparatus includes a detecting circuit and a calibrating circuit. The detecting circuit is arranged for generating a detection result by detecting relationship between edges of a plurality of signals generated from a plurality of signal sources, wherein at least one of the edges is a falling edge. The calibrating circuit is coupled to the detecting circuit, and arranged for calibrating at least one of the signal sources according to the detection result.

According to a second aspect of the present invention, an exemplary calibration method is disclosed. The exemplary method includes the following steps: generating a detection result by detecting relationship between edges of a plurality of signals generated from a plurality of signal sources, wherein at least one of the edges is a falling edge; and calibrating at least one of the signal sources according to the detection result.

According to a third aspect of the present invention, another exemplary calibration apparatus is disclosed. The exemplary calibration apparatus includes an edge distance detector and a calibrating circuit. The edge distance detector is arranged for detecting a distance between a first edge of a first signal generated from a first signal source and a second edge of a second signal generated from a second signal source. The calibrating circuit is coupled to the edge distance detector, and arranged for calibrating at least one of the signal sources according to the distance detected by the edge distance detector.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an electronic device employing a calibration apparatus according to a first exemplary embodiment of the present invention.

FIG. 2 is a diagram illustrating an exemplary implementation of a phase detector according to the present invention.

FIG. 3A is a diagram illustrating a process of using the phase detector shown in FIG. 2 for detecting leading/lagging relationship between rising edges of a first signal and a second signal before the second signal is calibrated.

FIG. 3B is a diagram illustrating a process of using the phase detector shown in FIG. 2 for detecting leading/lagging relationship between rising edges of the first signal and the second signal after the second signal is calibrated.

FIG. 3C is a diagram illustrating a process of using the phase detector shown in FIG. 2 for detecting leading/lagging relationship between rising edges of the first signal and the second signal after the adjusted second signal is calibrated again.

FIG. 4A is a diagram illustrating a process of using the phase detector shown in FIG. 2 for detecting leading/lagging relationship between a rising edge of a first signal and a falling edge of a second signal before the second signal is calibrated.

FIG. 4B is a diagram illustrating a process of using the phase detector shown in FIG. 2 for detecting leading/lagging relationship between a rising edge of the first signal and a falling edge of the second signal after the second signal is calibrated.

FIG. 4C is a diagram illustrating a process of using the phase detector shown in FIG. 2 for detecting leading/lagging relationship between a rising edge of the first signal and a falling edge of the second signal after the adjusted second signal is calibrated again.

FIG. 5A is a diagram illustrating a process of using the phase detector shown in FIG. 2 for detecting leading/lagging relationship between a falling edge of a first signal and a rising edge of a second signal before the second signal is calibrated.

FIG. 5B is a diagram illustrating a process of using the phase detector shown in FIG. 2 for detecting leading/lagging relationship between a falling edge of the first signal and a rising edge of the second signal after the second signal is calibrated.

FIG. 5C is a diagram illustrating a process of using the phase detector shown in FIG. 2 for detecting leading/lagging relationship between a falling edge of the first signal and a rising edge of the second signal after the adjusted second signal is calibrated again.

FIG. 6A is a diagram illustrating a process of using the phase detector shown in FIG. 2 for detecting leading/lagging relationship between falling edges of a first signal and a second signal before the second signal is calibrated.

FIG. 6B is a diagram illustrating a process of using the phase detector shown in FIG. 2 for detecting leading/lagging relationship between falling edges of the first signal and the second signal after the second signal is calibrated.

FIG. 6C is a diagram illustrating a process of using the phase detector shown in FIG. 2 for detecting leading/lagging relationship between falling edges of the first signal and the second signal after the adjusted second signal is calibrated again.

FIG. 7 is a diagram illustrating an exemplary implementation of an edge distance detector according to the present invention.

FIG. 8 is a diagram illustrating an exemplary operation of the edge distance detector shown in FIG. 7.

FIG. 9A is a diagram illustrating a process of using the edge distance detector shown in FIG. 7 for detecting the distance between a rising edge of a first signal and a falling edge of a second signal before the second signal is calibrated.

FIG. 9B is a diagram illustrating a process of using the edge distance detector shown in FIG. 7 for detecting the distance between a rising edge of the first signal and a falling edge of the second signal after the second signal is calibrated.

FIG. 9C is a diagram illustrating a process of using the edge distance detector shown in FIG. 7 for detecting the distance between a rising edge of the first signal and a falling edge of the second signal after the adjusted second signal is calibrated again.

FIG. 10 is a diagram illustrating an electronic device employing a calibration apparatus according to a second exemplary embodiment of the present invention.

FIG. 11 is a diagram illustrating an electronic device employing a calibration apparatus according to a third exemplary embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is electrically connected to another device, that connection may be through a direct electrical connection, or through an indirect electrical connection via other devices and connections.

The conception of the present invention is to employ phase detection or edge distance detection for monitoring the distortion caused by undesired non-ideal effects present at a transmitter chip, a receiver chip, and/or an interface between the transmitter chip and the receiver chip. By way of example, an employed phase detection scheme may be particularly designed to be capable of monitoring misalignment between rising edges of two signals, misalignment between falling edges of two signals, and misalignment between a rising edge of one signal and a falling edge of another signal. Similarly, an employed edge distance detection scheme may be particularly designed to be capable of monitoring a distance between rising edges of two signals, a distance between falling edges of two signals, and a distance between a rising edge of one signal and a falling edge of another signal. Further details are described hereinafter.

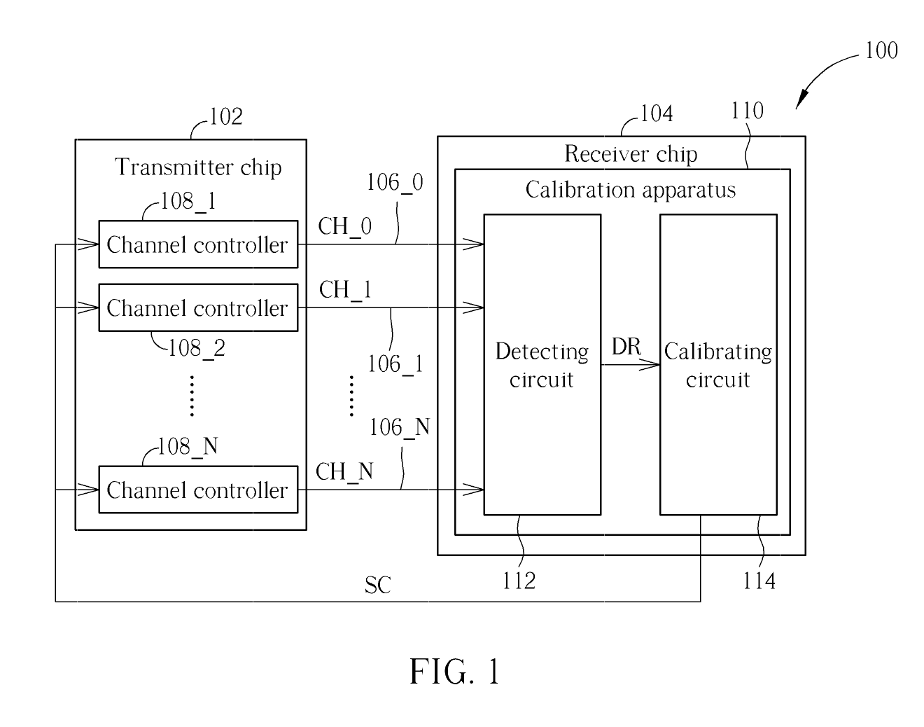

FIG. 1 is a diagram illustrating an electronic device employing a calibration apparatus according to a first exemplary embodiment of the present invention. The electronic device 100 includes a transmitter chip 102, a receiver chip 104, and a plurality of transmission lines 106_0-106_N coupled between the transmitter chip 102 and the receiver chip 104 for providing a plurality of channels CH_0-CH_N. For example, the electronic device 100 may be an optical storage apparatus (e.g., an optical disc drive), the transmitter chip 102 may be disposed in a controller, and the receiver chip 104 may be disposed in an optical pick-up unit (OPU). It should be noted that any application employing the hardware configuration shown in FIG. 1 falls within the scope of the present invention. As shown in FIG. 1, the transmitter chip 102 has a plurality of signal sources such as channel controllers 108_1-108_N, and an exemplary calibration apparatus 110 proposed by the present invention is disposed in the receiver chip 104. The receiver chip 104 is used for receiving signals generated from the channel controllers 108_1-108_N; besides, the received signals are also fed into the calibration apparatus 110. In this exemplary embodiment, the calibration apparatus 110 includes a detecting circuit 112 and a calibrating circuit 114. The detecting circuit 112 is arranged for generating a detection result DR by detecting relationship between edges of signals generated from the signal sources (e.g., channel controllers 108_1-108_N). The calibrating circuit 114 is coupled to the detecting circuit 112, and arranged for generating a calibration signal SC according to the detection result DR, wherein the calibration signal SC is used for calibrating at least one of the signal sources (e.g., channel controllers 108_1-108_N).

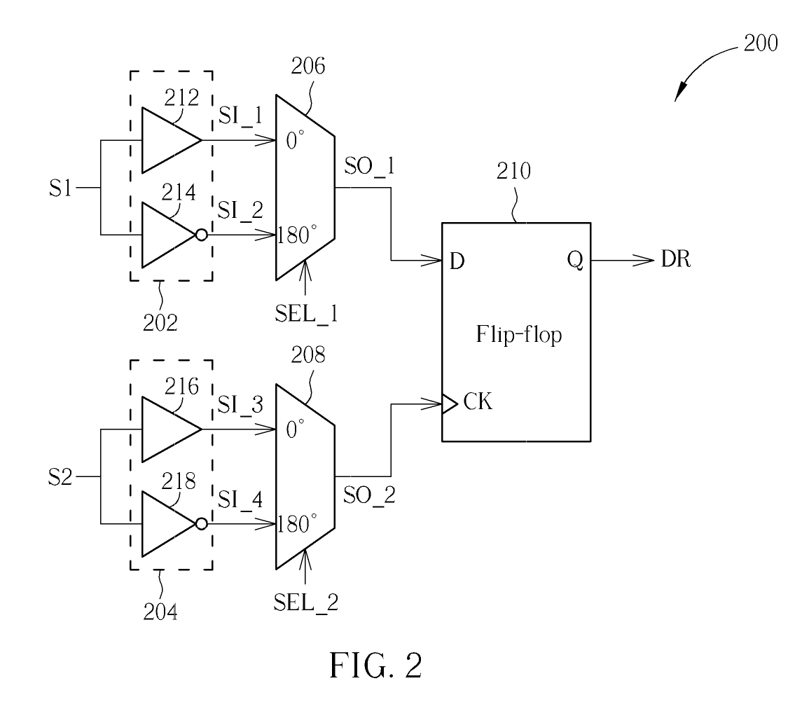

The detecting circuit 112 may be implemented using a phase detector capable of detecting whether a first edge of a first signal leads or lags behind a second edge of a second signal. It should be noted that the employed phase detector supports detection of misalignment between one edge being a falling edge and another edge being a rising edge or a falling edge. That is, at least one of the first edge and the second edge may be a falling edge. In addition, the employed phase detector may also support detection of misalignment between two rising edges. Please refer to FIG. 2, which is a diagram illustrating an exemplary implementation of a phase detector according to the present invention. The detecting circuit 112 may be realized by the phase detector 200 shown in FIG. 2. The phase detector 200 is arranged for detecting the leading/lagging relationship between any two of the signals received by the receiver chip 104. That is, the received signals include a first signal S1 generated from one of the channel controllers 108_1-108_N and a second signal S2 generated from another of the signal sources 108_1-108_N. The phase detector 200 includes, but is not limited to, a first processing unit 202, a second processing unit 204, a first selector 206, a second selector 208, and a flip-flop (e.g., a D-type flip-flop) 210.

The first processing unit 202 is arranged for generating a first input signal SI_1 and a second input signal SI_2 according to the first signal S1, wherein the first input signal SI_1 and the second input signal SI_2 are out of phase (i.e., the first input signal SI_1 and the second input signal SI_2 have a 180-degree phase difference therebetween). In this exemplary embodiment, the first processing unit 202 includes a non-inverting buffer 212 for buffering the first signal S1 to thereby output the first input signal SI_1, and an inverting buffer 214 for buffering the same first signal S1 to thereby output the second input signal SI_2.

Regarding the second processing unit 204, it is arranged for generating a third input signal SI_3 and a fourth input signal SI_4 according to the second signal S2, wherein the third input signal SI_3 and the fourth input signal SI_4 are out of phase (i.e., the third input signal SI_3 and the fourth input signal SI_4 have a 180-degree phase difference therebetween). In this exemplary embodiment, the second processing unit 204 includes a non-inverting buffer 216 for buffering the second signal S2 to thereby output the third input signal SI_3, and an inverting buffer 218 for buffering the same second signal S2 to thereby output the fourth input signal SI_4.

The first selector 206 is arranged for selecting one of the first input signal SI_1 and the second input signal SI_2 as a first output signal SO_1. For example, if a rising edge of the first signal S1 is to be monitored for phase detection, the first selector 206 is controlled by a first selection signal SEL1 to output the first input signal SI_1 as the first output signal SO_1 (i.e., SO_1=SI_1). However, if a falling edge of the first signal S1 is to be monitored for phase detection, the first selector 206 is controlled by the first selection signal SEL_1 to output the second input signal SI_2 as the first output signal SO_1 (i.e., SO_1=SI_2).

Regarding the second selector 208, it is arranged for selecting one of the third input signal SI_3 and the fourth input signal SI_4 as a second output signal SO_2. For example, if a rising edge of the second signal S2 is to be monitored for phase detection, the second selector 208 is controlled by a second selection signal SEL_2 to output the third input signal SI_3 as the second output signal SO_2 (i.e., SO_2=SI_3). However, if a falling edge of the second signal S2 is to be monitored for phase detection, the second selector 208 is controlled by the second selection signal SEL_2 to output the fourth input signal SI_4 as the second output signal SO_2 (i.e., SO_2=SI_4).

As shown in FIG. 2, the flip-flop 210 has a data input port D arranged for receiving the first output signal SO_1, a clock input port CK arranged for receiving the second output signal SO_2 used to act as a sampling clock, and a data output port Q arranged for generating the detection result DR. For example, the flip-flop 210 is triggered by rising edges. Therefore, when the second output signal SO_2 has a rising edge, the instant logic value of the first output signal SO_1 is sampled by the flip-flop 210 to set the detection result DR indicative of the leading/lagging relationship between two edges.

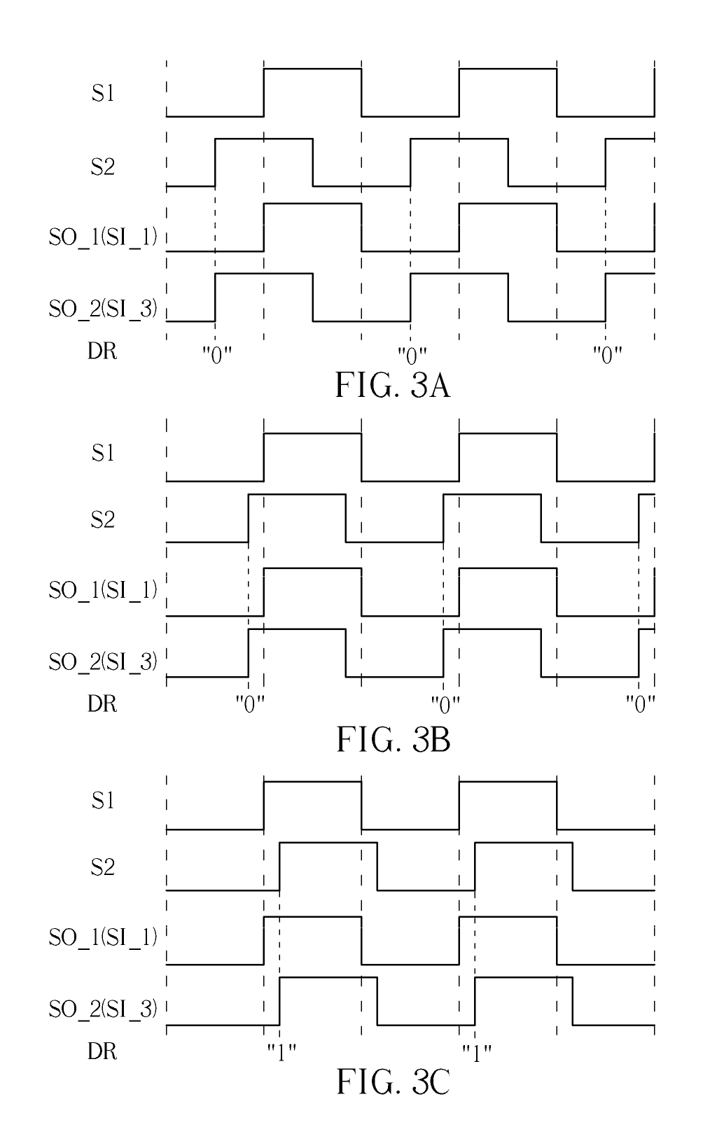

Please refer to FIG. 3A, FIG. 3B, and FIG. 3C together. FIG. 3A is a diagram illustrating a process of using the phase detector 200 shown in FIG. 2 for detecting the leading/lagging relationship between rising edges of the first signal S1 and the second signal S2 before the second signal S2 is calibrated. FIG. 3B is a diagram illustrating a process of using the phase detector 200 shown in FIG. 2 for detecting the leading/lagging relationship between rising edges of the first signal S1 and the second signal S2 after the second signal S2 is calibrated. FIG. 3C is a diagram illustrating a process of using the phase detector 200 shown in FIG. 2 for detecting the leading/lagging relationship between rising edges of the first signal S1 and the second signal S2 after the adjusted second signal S2 is calibrated again.

As shown in FIG. 3A, the detection result DR would be set by the low logic value “0” due to the fact that the rising edge of the first output signal SO_1 lags behind the rising edge of the second output signal SO_2. This also implies that the rising edge of the first signal S1 lags behind the rising edge of the second signal S2. When notified by the detection result DR indicative of the edge misalignment, the calibrating circuit 114 shown in FIG. 1 calibrates at least one of the signal sources that generate the first signal S1 and the second signal S2. Suppose that the first signal S1 is generated from the channel controller 108_1, and the second signal S2 is generated from the channel controller 108_2. In one exemplary design, the first signal S1 is fixed and the calibrating circuit 114 calibrates the channel controller 108_2 to make the phase of the second signal S2 shifted forward, as shown in FIG. 3B. As can be seen from FIG. 3B, the detection result DR would also be set by the low logic value “0” due to the fact that the rising edge of the first output signal SO_1 still lags behind the rising edge of the second output signal SO_2. This still implies that the rising edge of the first signal S1 lags behind the rising edge of the second signal S2. Similarly, when notified by the detection result DR, the calibrating circuit 114 calibrates the channel controller 108_2 again for making the phase of the second signal S2 shifted forward, as shown in FIG. 3C. As can be seen from FIG. 3C, the detection result DR would be set by the high logic value “1” due to the fact that the rising edge of the first output signal SO_1 now leads the rising edge of the second output signal SO_2. This implies that the rising edge of the first signal S1 now leads the rising edge of the second signal S2. The calibration process based on the phase detection result derived from processing the first signal S1 and the second signal S2 is accomplished.

It should be noted that the illustrated phase adjusting step made to the second signal S2 is for illustrative purposes only. Actually, the phase adjusting step may be adjusted, depending upon the design consideration/requirement. For example, when a smaller phase adjusting step is adopted, the calibration process is capable of making the rising edge of the calibrated second signal S2 closer to or exactly aligned with the rising edge of the first signal S1.

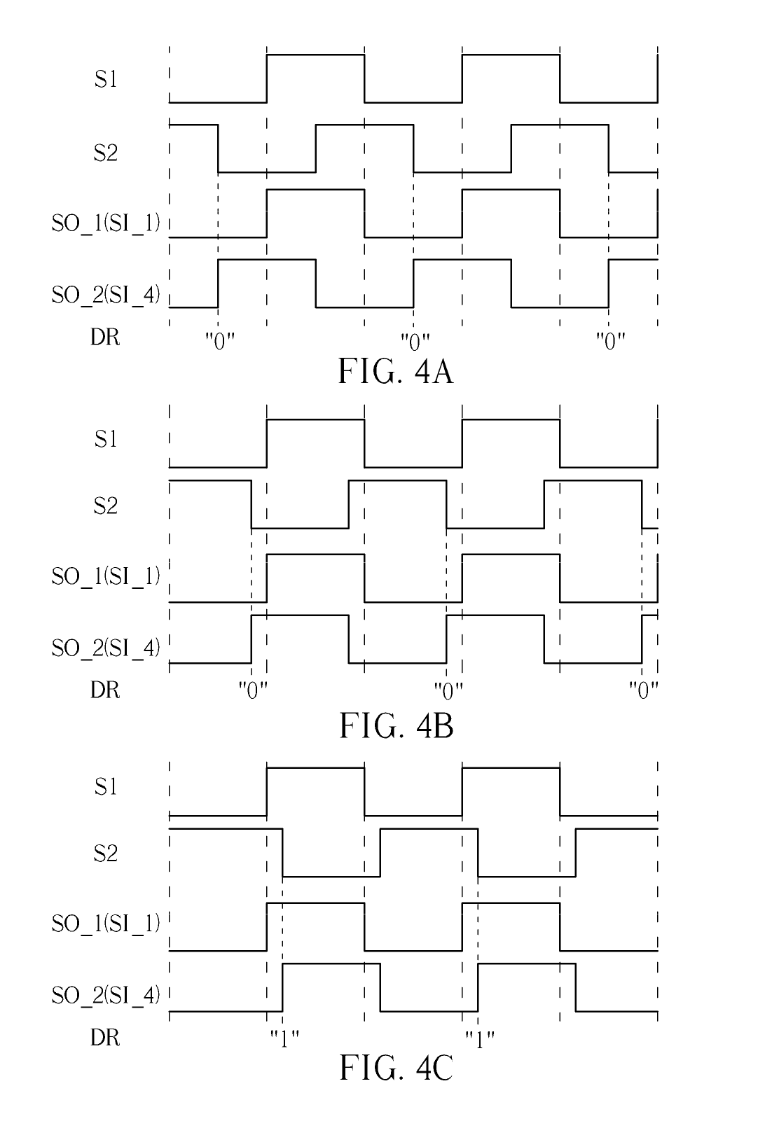

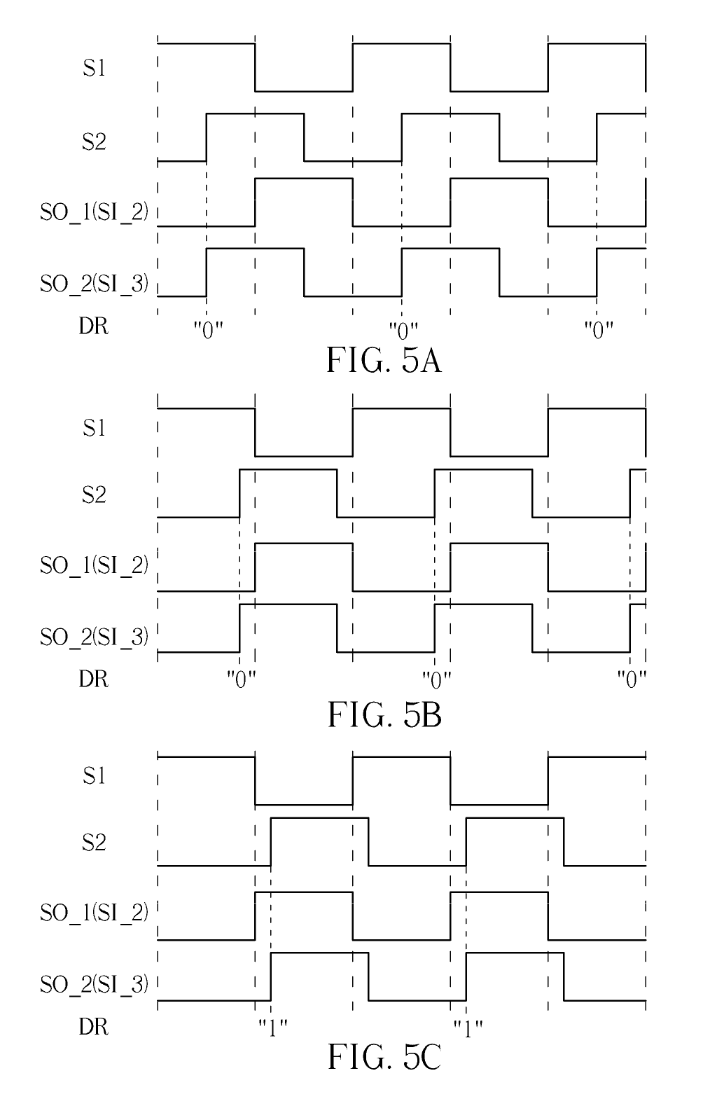

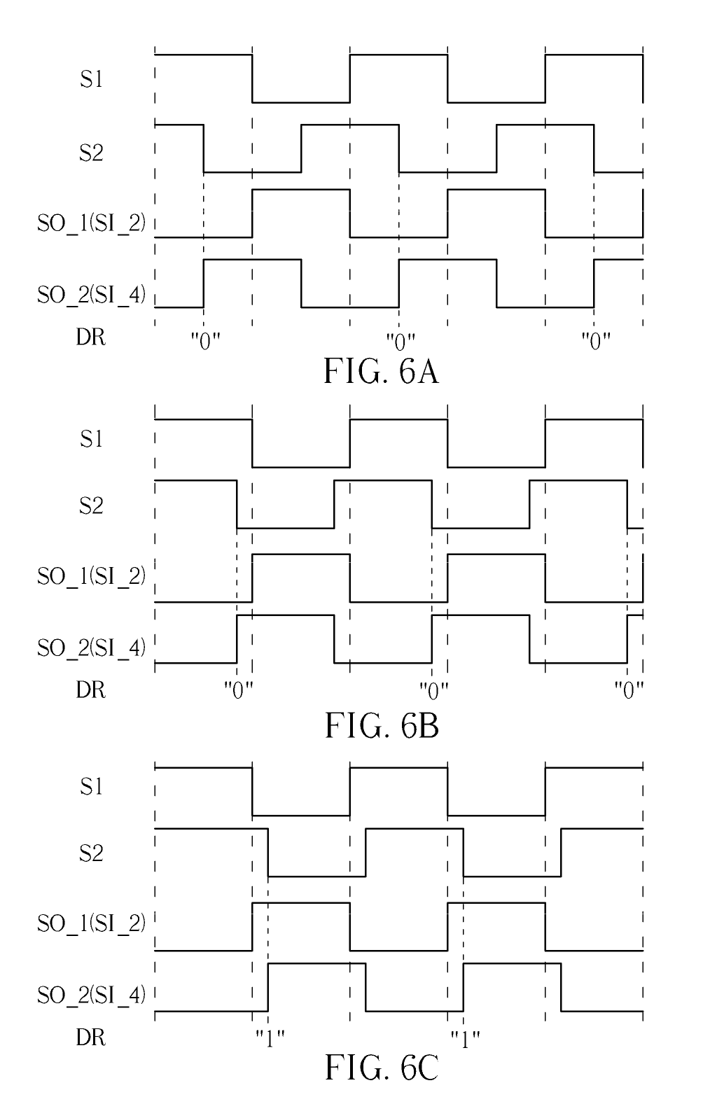

An exemplary process of using the phase detector 200 shown in FIG. 2 for detecting the leading/lagging relationship between a rising edge of the first signal S1 and a falling edge of the second signal S2 is shown in FIG. 4A, FIG. 4B, and FIG. 4C. An exemplary process of using the phase detector 200 shown in FIG. 2 for detecting the leading/lagging relationship between a falling edge of the first signal S1 and a rising edge of the second signal S2 is shown in FIG. 5A, FIG. 5B, and FIG. 5C. An exemplary process of using the phase detector 200 shown in FIG. 2 for detecting the leading/lagging relationship between falling edges of the first signal S1 and the second signal S2 is shown in FIG. 6A, FIG. 6B, and FIG. 6C. As a person skilled in the art can readily understand the phase detection operations shown in FIGS. 4A-6C after reading above paragraphs, further description is omitted here fore brevity.

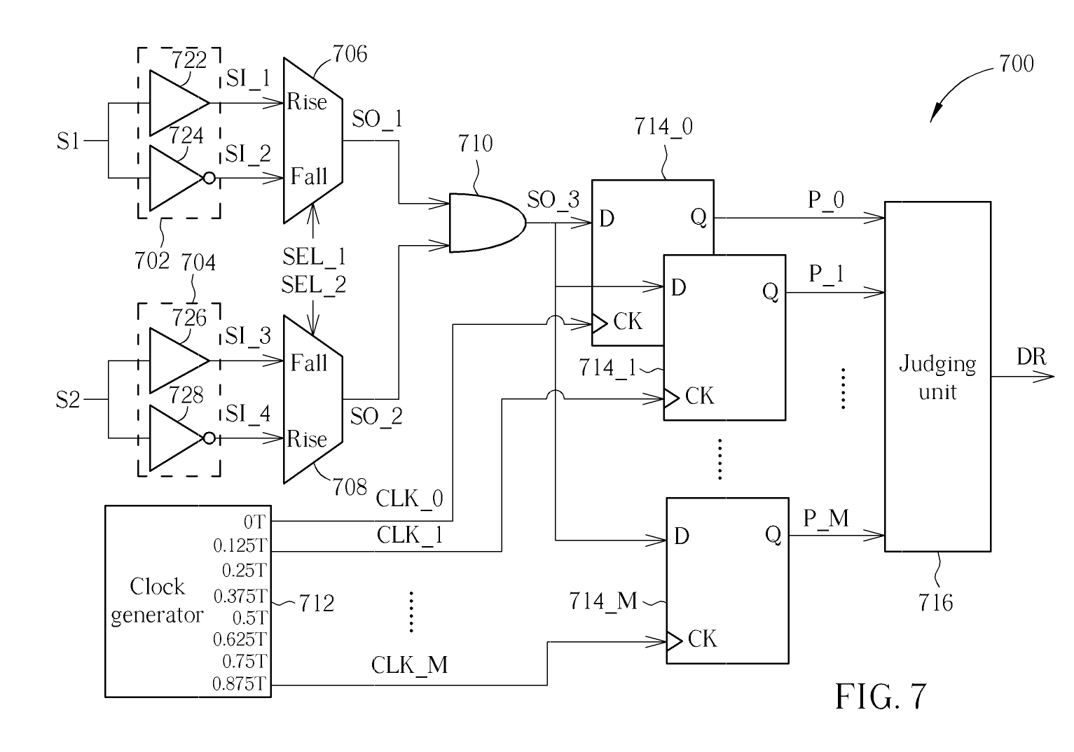

Alternatively, the detecting circuit 112 may be implemented using an edge distance detector capable of detecting a distance between a first edge of a first signal and a second edge of a second signal. It should be noted that the employed edge distance detector supports detection of a distance between one edge that may be a falling edge or a rising edge and another edge that may be a rising edge or a falling edge. Please refer to FIG. 7, which is a diagram illustrating an exemplary implementation of an edge distance detector according to the present invention. The detecting circuit 112 shown in FIG. 1 may be realized by the edge distance detector 700 shown in FIG. 7. The edge distance detector 700 is arranged for detecting a distance between any two of the signals received by the receiver chip 104. That is, the received signals include a first signal S1 generated from one of the channel controllers 108_1-108_N and a second signal S2 generated from another of the signal sources 108_1-108_N. The edge distance detector 700 includes, but is not limited to, a first processing unit 702, a second processing unit 704, a first selector 706, a second selector 708, a logic circuit 710, a clock generator 712, a plurality of flip-flops (e.g., D-type flip-flops) 714_0-714_M, and a judging unit 716.

The first processing unit 702 is arranged for generating a first input signal SI_1 and a second input signal SI_2 according to the first signal S1, wherein the first input signal SI_1 and the second input signal SI_2 are out of phase (i.e., the first input signal SI_1 and the second input signal SI_2 have a 180-degree phase difference therebetween). In this exemplary embodiment, the first processing unit 702 includes a non-inverting buffer 722 for buffering the first signal S1 to thereby output the first input signal SI_1, and an inverting buffer 724 for buffering the same first signal S1 to thereby output the second input signal SI_2.

Regarding the second processing unit 704, it is arranged for generating a third input signal SI_3 and a fourth input signal SI_4 according to the second signal S2, wherein the third input signal SI_3 and the fourth input signal SI_4 are out of phase (i.e., the third input signal SI_3 and the fourth input signal SI_4 have a 180-degree phase difference therebetween). In this exemplary embodiment, the second processing unit 704 includes a non-inverting buffer 726 for buffering the second signal S2 to thereby output the third input signal SI_3, and an inverting buffer 728 for buffering the same second signal S2 to thereby output the fourth input signal SI_4.

The first selector 706 is arranged for selecting one of the first input signal SI_1 and the second input signal SI_2 as a first output signal SO_1. For example, if a rising edge of the first signal S1 is to be monitored for edge distance detection, the first selector 706 is controlled by a first selection signal SEL1 to output the first input signal SI_1 as the first output signal SO_1 (i.e., SO_1=SI_1). However, if a falling edge of the first signal S1 is to be monitored for edge distance detection, the first selector 706 is controlled by the first selection signal SEL_1 to output the second input signal SI_2 as the first output signal SO_1 (i.e., SO_1=SI_2).

Regarding the second selector 708, it is arranged for selecting one of the third input signal SI_3 and the fourth input signal SI_4 as a second output signal SO_2. For example, if a falling edge of the second signal S2 is to be monitored for edge distance detection, the second selector 708 is controlled by a second selection signal SEL_2 to output the third input signal SI_3 as the second output signal SO_2 (i.e., SO_2=SI_3). However, if a rising edge of the second signal S2 is to be monitored for edge distance detection, the second selector 708 is controlled by the second selection signal SEL_2 to output the fourth input signal SI_4 as the second output signal SO_2 (i.e., SO_2=SI_4).

The logic circuit 710 is arranged for generating a logic output SO_3 by performing a predetermined logic operation upon the first output signal SO_1 and the second output signal SO_2. Specifically, the generated logic output SO_3 would carry edge distance information of monitored edges of the first signal 51 and the second signal S2. In this exemplary embodiment, the logic circuit 702 is implemented using an AND gate. Thus, the duration of the high logic value “1” is representative of the distance between monitored edges of the first signal S1 and the second signal S2. However, using an AND gate to realize the logic circuit 710 is for illustrative purposes. The logic circuit 710 may be realized by a different logic gate or combinational logic as long as the logic output SO_3 having desired edge distance information included therein is successfully generated to the following signal processing stage.

The clock generator 712 is arranged for generating a plurality of sampling clocks CLK_0-CLK_M having the same frequency but difference phases. By way of example, but not limitation, the clock generator 712 may be implemented using a phase-locked loop (PLL), and a phase difference between two sampling clocks with adjacent phases may be 0.1 25T, where T is the period of the sampling clock. Each of the flip-flops 714_0-714_M has a data input port D, a data output port Q, and a clock input port CK. As shown in FIG. 7, data input ports D of the flip-flops 714_0-714_M are arranged for receiving the same logic output SO_3, and the clock generator 712 generates the sampling clocks CLK_0-CLK_M to clock input ports CK of the flip-flops 714_0-714_M respectively. To put it another way, the same logic output SO_3 would be sampled by multiple sampling clocks CLK_0-CLK_M having difference phases, and the resultant sampled values P_0-P_M are generated from data output ports Q of the flip-flops 714_0-714_M. Based on the sampled values P_0-P_M, the judging unit 716 generates the detection result DR accordingly. For example, the judging unit 716 may count the number of 1's or 0's among the sampled values to estimate the edge distance.

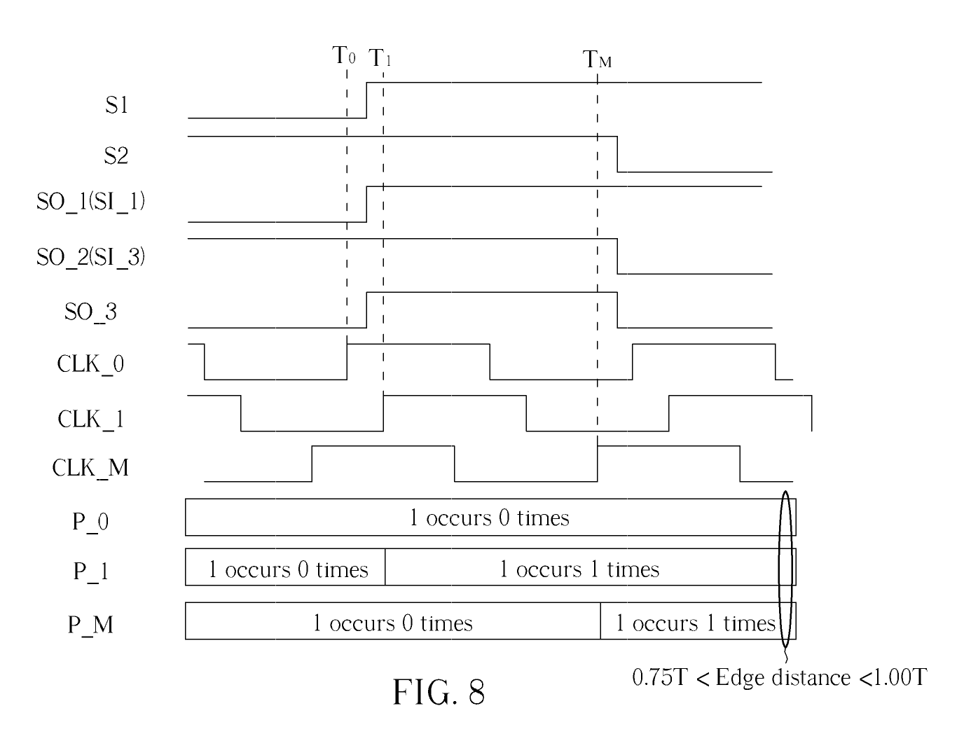

Please refer to FIG. 8 for better understanding of the edge distance detection scheme. Consider a case where the edge distance detector 700 is employed for detecting a distance between rising edge of the first signal S1 and falling edge of the second signal S2, and the phase difference between two sampling clocks with adjacent phases is 0.125T. Thus, the number of the sampling clocks CLK_0-CLK_M is equal to 8. The first selector 706 outputs the first input signal SI_1 as the first output signal SO_1, and the second selector 708 outputs the third input signal SI_3 as the second output signal SO_2. As can be seen from FIG. 8, the sampled value P_0 is equal to the low logic value “0” at the sampling timing T₀, the sampled value P_1 is equal to the high logic value “1” at the sampling timing T₁, and the sampled value P_M is also equal to the high logic value “1” at the sampling timing T_{M}. As there would be seven sampled values with the high logic value “1” and only one sampled value with the low logic value “0”, the judging unit 716 therefore generates the detection result DR to indicate that the edge distance between rising edge of the first signal S1 and falling edge of the second signal S2 is larger than 0.75T and smaller than 1.00T.

Suppose that the first signal S1 is generated from the channel controller 108_1, and the second signal S2 is generated from the channel controller 108_2. The calibrating circuit 114 shown in FIG. 1 is therefore arranged to selectively calibrate at least one of the channel controllers 108_1 and 108_2 by checking if the edge distance estimated by the edge distance detector 700 falls within a target range TR delimited by D1 and D2.

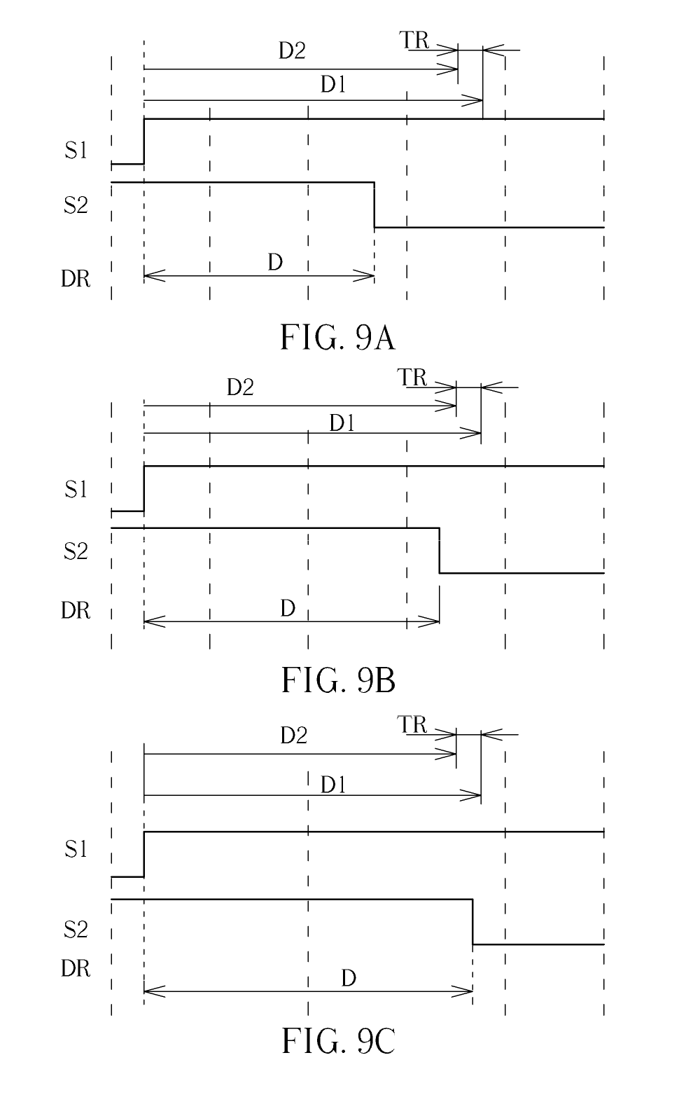

Please refer to FIG. 9A, FIG. 9B, and FIG. 9C together. FIG. 9A is a diagram illustrating a process of using the edge distance detector 700 shown in FIG. 7 for detecting the distance between a rising edge of the first signal S1 and a falling edge of the second signal S2 before the second signal S2 is calibrated. FIG. 9B is a diagram illustrating a process of using the edge distance detector 700 shown in FIG. 7 for detecting the distance between a rising edge of the first signal S1 and a falling edge of the second signal S2 after the second signal S2 is calibrated. FIG. 9C is a diagram illustrating a process of using the edge distance detector 700 shown in FIG. 7 for detecting the distance between a rising edge of the first signal S1 and a falling edge of the second signal S2 after the adjusted second signal S2 is calibrated again.

As shown in FIG. 9A, the detection result DR would indicate that the distance D between the rising edge of the first signal S1 and the falling edge of the second signal S2 does not fall within the target range TR. When notified by the detection result DR, the calibrating circuit 114 shown in FIG. 1 calibrates at least one of the signal sources that generate the first signal S1 and the second signal S2. In one exemplary design, the first signal S1 is fixed and the calibrating circuit 114 calibrates the channel controller 108_2 to make the phase of the second signal S2 shifted forward, as shown in FIG. 9B. As can be seen from FIG. 9B, the detection result DR would still indicate that the distance D between the rising edge of the first signal S1 and the falling edge of the second signal S2 does not fall within the target range TR. Similarly, when notified by the detection result DR, the calibrating circuit 114 calibrates the channel controller 108_2 again for making the phase of the second signal S2 shifted forward, as shown in FIG. 9C. As can be seen from FIG. 9C, the detection result DR now indicates that the distance D between the rising edge of the first signal S1 and the falling edge of the second signal S2 falls within the target range TR. The calibration process based on the edge distance detection result derived from processing the first signal S1 and the second signal S2 is accomplished. It should be noted that the illustrated phase adjusting step made to the second signal S2 is for illustrative purposes only. Actually, the phase adjusting step may be adjusted, depending upon the design consideration/requirement.

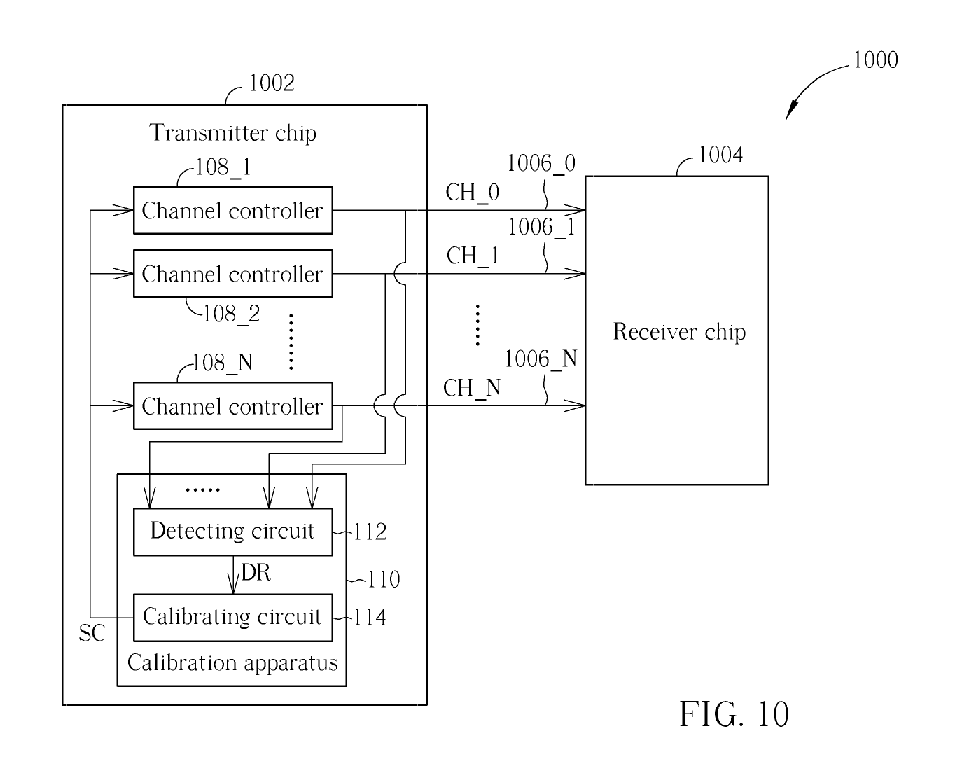

Regarding the electronic device 100 shown in FIG. 1, the calibration apparatus 110 is disposed in the receiver chip 104 for compensating the received signals for the distortion caused by the non-ideal effects present at the transmitter chip 102, the receiver chip 104, and/or the interface between the transmitter chip 102 and the receiver chip 104. However, this is for illustrative purposes only, and is not meant to be a limitation of the present invention. That is, any application employing the calibration apparatus 110 falls within the scope of the present invention. Please refer to FIG. 10, which is a diagram illustrating an electronic device employing a calibration apparatus according to a second exemplary embodiment of the present invention. The electronic device 1000 includes a transmitter chip 1002, a receiver chip 1004, and a plurality of transmission lines 1006_0-1006_N coupled between the transmitter chip 1002 and the receiver chip 1004 for providing a plurality of channels CH_0-CH_N. By way of example, but not limitation, the electronic device 1000 may be an optical storage apparatus (e.g., an optical disc drive), the transmitter chip 1002 may be disposed in a controller, and the receiver chip 1004 may be disposed in an OPU. It should be noted that any application employing the hardware configuration shown in FIG. 10 falls within the scope of the present invention.

The major difference between the electronic devices 100 and 1000 is that the calibration apparatus 110 is disposed in the transmitter chip 1002 in which the signal sources (e.g., channel controllers 108_1-108_N) are disposed. An objective of calibrating the signal sources to compensate the transmitted signals for distortion caused by non-ideal effects present at the transmitter chip 1002 is achieved. Regarding the detecting circuit 112 disposed in the transmitter chip 1002, it may be implemented using the phase detector 200 shown in FIG. 2 or the edge distance detector 700 shown in FIG. 7. As a person skilled in art can readily understand the calibration process performed by the calibration apparatus 110 shown in FIG. 10 after reading above paragraphs, further description is omitted here for brevity.

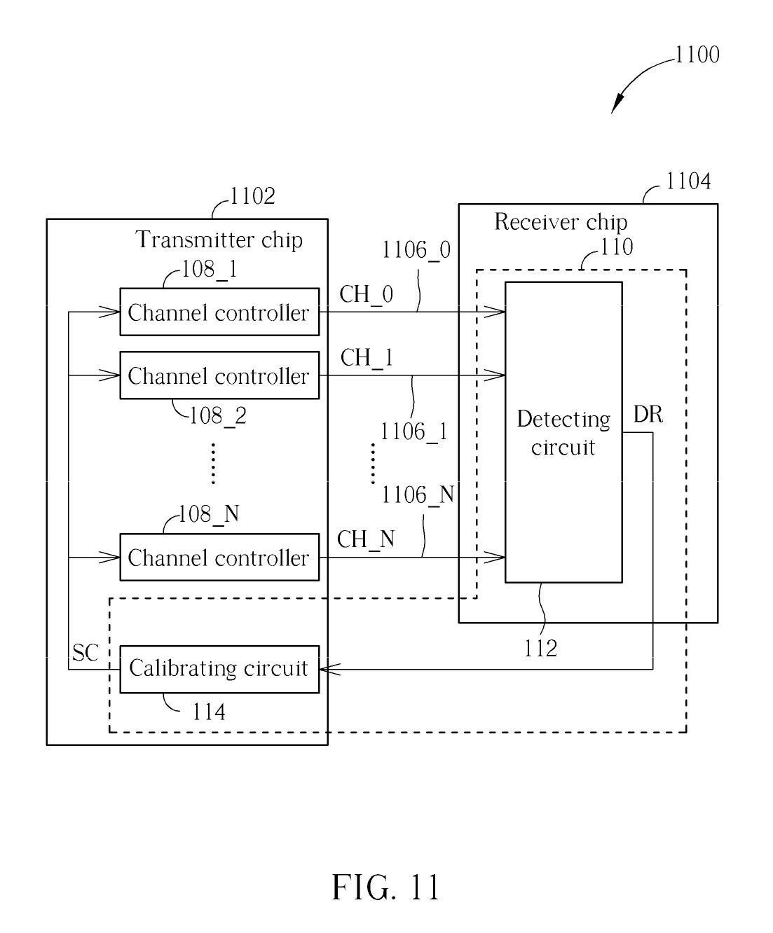

Please refer to FIG. 11, which is a diagram illustrating an electronic device employing a calibration apparatus according to a third exemplary embodiment of the present invention. The electronic device 1100 includes a transmitter chip 1102, a receiver chip 1104, and a plurality of transmission lines 1106_0-1106_N coupled between the transmitter chip 1102 and the receiver chip 1104 for providing a plurality of channels CH_0-CH_N. By way of example, but not limitation, the electronic device 1100 may be an optical storage apparatus (e.g., an optical disc drive), the transmitter chip 1102 may be disposed in a controller, and the receiver chip 1104 may be disposed in an OPU. It should be noted that any application employing the hardware configuration shown in FIG. 11 falls within the scope of the present invention.

The major difference between the electronic devices 100 and 1100 is that the calibrating circuit 114 of the calibration apparatus 110 is disposed in the transmitter chip 1102 in which the signal sources (e.g., channel controllers 108_1-108_N) are disposed, and the detecting circuit 112 of the calibration apparatus 110 is disposed in the receiver chip 1104. An objective of calibrating the signal sources to compensate the transmitted signals for distortion caused by non-ideal effects present at the transmitter chip 1102, the receiver chip 1104 and/or the interface between the transmitter chip 1102 and the receiver chip 1104 is achieved. Regarding the detecting circuit 112 disposed in the receiver chip 1102, it may be implemented using the phase detector 200 shown in FIG. 2 or the edge distance detector 700 shown in FIG. 7. As a person skilled in art can readily understand the calibration process performed by the calibration apparatus 110 shown in FIG. 11 after reading above paragraphs, further description is omitted here for brevity.

It should be noted that the signals generated from the channel controllers 108_1 -108_N shown in FIG. 1/FIG. 10/FIG. 11 during the calibration process are not required to be periodical signals. In a case where the processing speed of the detecting circuit 112 is high, using the channel controllers 108_1-108_N to provide non-periodical signals for signal calibration may be feasible. Moreover, when the processing speed of the detecting circuit 112 is high, the employed phase detection scheme/edge distance detection scheme may be capable of processing more than two signals, and the calibrating circuit 114 may be allowed to calibrate multiple signal sources at the same time.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A calibration apparatus, comprising:
a detecting circuit, arranged for generating a detection result by detecting relationship between edges of a plurality of signals generated from a plurality of signal sources, wherein at least one of the edges is a falling edge; and
a calibrating circuit, coupled to the detecting circuit and arranged for calibrating at least one of the signal sources according to the detection result.

2. The calibration apparatus of claim 1, wherein the detecting circuit and the signal sources are disposed in a same transmitter chip.

3. The calibration apparatus of claim 1, wherein the signal sources are disposed in a transmitter chip, and the detecting circuit is disposed in a receiver chip which is arranged for receiving the signals from the transmitter chip.

4. The calibration apparatus of claim 1, wherein the signals include a first signal generated from a first signal source and a second signal generated from a second signal source; and the detecting circuit is a phase detector arranged for detecting whether a first edge of the first signal leads or lags behind a second edge of the second signal, where at least one of the first edge and the second edge is a falling edge.

5. The calibration apparatus of claim 1, wherein the signals include a first signal generated from a first signal source and a second signal generated from a second signal source; and the detecting circuit comprises:
a first processing unit, arranged for generating a first input signal and a second input signal according to the first signal, wherein the first input signal and the second input signal are out of phase;
a second processing unit, arranged for generating a third input signal and a fourth input signal according to the second signal, wherein the third input signal and the fourth input signal are out of phase;
a first selector, arranged for selecting one of the first input signal and the second input signal as a first output signal;
a second selector, arranged for selecting one of the third input signal and the fourth input signal as a second output signal; and
a flip-flop, having a data input port arranged for receiving the first output signal, a clock input port arranged for receiving the second output signal, and a data output port arranged for generating the detection result.

6. The calibration apparatus of claim 1, wherein the signals include a first signal generated from a first signal source and a second signal generated from a second signal source; and the detecting circuit is an edge distance detector arranged for detecting a distance between a first edge of the first signal and a second edge of the second signal, where at least one of the first edge and the second edge is a falling edge.

7. The calibration apparatus of claim 6, wherein the calibrating circuit selectively calibrates at least one of the first signal source and the second signal source by checking if the distance falls within a target range.

8. The calibration apparatus of claim 1, wherein the signals include a first signal generated from a first signal source and a second signal generated from a second signal source; and the detecting circuit comprises:
a first processing unit, arranged for generating a first input signal and a second input signal according to the first signal, wherein the first input signal and the second input signal are out of phase;
a second processing unit, arranged for generating a third input signal and a fourth input signal according to the second signal, wherein the third input signal and the fourth input signal are out of phase;
a first selector, arranged for selecting one of the first input signal and the second input signal as a first output signal;
a second selector, arranged for selecting one of the third input signal and the fourth input signal as a second output signal;
a logic circuit, arranged for generating a logic output by performing a predetermined logic operation upon the first output signal and the second output signal;
a clock generator, arranged for generating a plurality of sampling clocks with difference phases;
a plurality of flip-flops, each having a data input port, a data output port, and a clock input port, wherein data input ports of the flip-flops are arranged for receiving the logic output, and clock input ports of the flip-flops are arranged for receiving the sampling clocks respectively; and
a judging unit, arranged for generating the detection result according to outputs at the data output ports of the flip-flops.

9. The calibration apparatus of claim 8, wherein the calibrating circuit selectively calibrates at least one of the first signal source and the second signal source by checking if the distance falls within a target range.

10. A calibration method, comprising:
generating a detection result by detecting relationship between edges of a plurality of signals generated from a plurality of signal sources, wherein at least one of the edges is a falling edge; and
calibrating at least one of the signal sources according to the detection result.

11. The calibration method of claim 10, wherein the signal sources are disposed in a transmitter chip, and the step of generating the detection result is performed in the same transmitter chip.

12. The calibration method of claim 10, wherein the signal sources are disposed in a transmitter chip, and the step of generating the detection result is performed in a receiver chip which is arranged for receiving the signals from the transmitter chip.

13. The calibration method of claim 10, wherein the signals include a first signal generated from a first signal source and a second signal generated from a second signal source; and the step of generating the detection result comprises:
detecting whether a first edge of the first signal leads or lags behind a second edge of the second signal, where at least one of the first edge and the second edge is a falling edge.

14. The calibration method of claim 10, wherein the signals include a first signal generated from a first signal source and a second signal generated from a second signal source; and the step of generating the detection result comprises:
generating a first input signal and a second input signal according to the first signal, wherein the first input signal and the second input signal are out of phase;
generating a third input signal and a fourth input signal according to the second signal, wherein the third input signal and the fourth input signal are out of phase;
selecting one of the first input signal and the second input signal as a first output signal;
selecting one of the third input signal and the fourth input signal as a second output signal;
transmitting the first output signal to a data input port of a flip-flop;
transmitting the second output signal to a clock input port of the flip-flop; and
deriving the detection result from an output at a data output port of the flip-flop.

15. The calibration method of claim 10, wherein the signals include a first signal generated from a first signal source and a second signal generated from a second signal source; and the step of generating the detection result comprises:
detecting a distance between a first edge of the first signal and a second edge of the second signal, where at least one of the first edge and the second edge is a falling edge.

16. The calibration method of claim 15, wherein the step of calibrating at least one of the signal sources comprises:
selectively calibrating at least one of the first signal source and the second signal source by checking if the distance falls within a target range.

17. The calibration method of claim 10, wherein the signals include a first signal generated from a first signal source and a second signal generated from a second signal source; and the step of generating the detection result comprises:
generating a first input signal and a second input signal according to the first signal, wherein the first input signal and the second input signal are out of phase;
generating a third input signal and a fourth input signal according to the second signal, wherein the third input signal and the fourth input signal are out of phase;
selecting one of the first input signal and the second input signal as a first output signal;
selecting one of the third input signal and the fourth input signal as a second output signal;
generating a logic output by performing a predetermined logic operation upon the first output signal and the second output signal;
generating a plurality of sampling clocks with difference phases;
transmitting the logic output to data input ports of a plurality of flip-flops;
transmitting the sampling clocks to clock input ports of the flip-flops, respectively; and
deriving the detection result from outputs at data output ports of the flip-flops.

18. The calibration method of claim 17, wherein the step of calibrating at least one of the signal sources comprises:
selectively calibrating at least one of the first signal source and the second signal source by checking if the distance falls within a target range.

19. A calibration apparatus, comprising:
an edge distance detector, arranged for detecting a distance between a first edge of a first signal generated from a first signal source and a second edge of a second signal generated from a second signal source; and
a calibrating circuit, coupled to the edge distance detector and arranged for calibrating at least one of the signal sources according to the distance detected by the edge distance detector.

20. The calibration apparatus of claim 19, wherein the edge distance detector comprises:
a first processing unit, arranged for generating a first input signal and a second input signal according to the first signal, wherein the first input signal and the second input signal are out of phase;
a second processing unit, arranged for generating a third input signal and a fourth input signal according to the second signal, wherein the third input signal and the fourth input signal are out of phase;
a first selector, arranged for selecting one of the first input signal and the second input signal as a first output signal;
a second selector, arranged for selecting one of the third input signal and the fourth input signal as a second output signal;
a logic circuit, arranged for generating a logic output by performing a predetermined logic operation upon the first output signal and the second output signal;
a clock generator, arranged for generating a plurality of sampling clocks with difference phases;
a plurality of flip-flops, each having a data input port, a data output port, and a clock input port, wherein data input ports of the flip-flops are arranged for receiving the logic output, and clock input ports of the flip-flops are arranged for receiving the sampling clocks respectively; and
a judging unit, arranged for determining the distance according to outputs at the data output ports of the flip-flops.

21. The calibration apparatus of claim 19, wherein the calibrating circuit selectively calibrates at least one of the first signal source and the second signal source by checking if the distance falls within a target range.
